(19) United States
(12) Patent Application Publication
(10) Pub. No.: US 2010/0031501 A1
(43) Pub. Date: Feb. 11, 2010

(54) METHOD FOR FILLING THROUGH HOLE OR NON-THROUGH HOLE FORMED ON BOARD WITH FILLER

(75) Inventors: Shigenobu Sekine, Katsushika-Ku (JP); Yurina Sekine, Katsushika-Ku (JP); Yoshiharu Kuwana, Katsushika-Ku (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Napra Co., Ltd., Katsushika-Ku (JP)

(21) Appl. No.: 12/188,790

(22) Filed: Aug. 8, 2008

(51) Int. Cl. H05K 3/40; H05K 3/00

(52) U.S. Cl. 29/852

(57) ABSTRACT

A method for filling a through hole or a non-through hole formed on a board with a fluent filler comprises combining at least one filling method selected from a centrifugal filling method and a magnetic filling method with an ultrasonic filling method.

### BACKGROUND OF THE INVENTION

1. Field of the Invention

The present invention relates to a method for filling a through hole or a non-through hole formed on a board such as a multilayer circuit board or a wafer with a filler.

2. Description of the Related Art

It is publicly known to fill a throughhole or a non-through hole formed on a board such as a multilayer circuit board or a wafer with a liquid viscous material such as a nanoparticulate paste or an insulating resin paste. For example, Japanese Patent No. 3198273 discloses a method for filling a through hole or a non-through hole of a board with a liquid viscous material, wherein after stencil printing of the liquid viscous material on a circuit board in a vacuum atmosphere, the degree of vacuum of the vacuum atmosphere is lowered, or the vacuum atmosphere is turned to a usual atmospheric pressure atmosphere, thereby achieving differential pressure filling.

The invention disclosed in Japanese Patent No. 3198273 was the subject to a through hole or a non-through hole of a multilayer circuit board having a diameter of more than 50 μm and a ratio of (hole depth L)/(hole diameter D) (L/D ratio, namely an aspect ratio) in the range of from about 2 to 3.

However, in recent years, it has been demanded to realize holes having a diameter of not more than 25 μm and an aspect ratio of 5 or more. It has been noted that when an existing method represented by the method disclosed in Japanese Patent No. 3198273 or the like is applied to such holes, there is caused a problem that an unfilled portion is easy to remain especially in the bottom of a non-through hole.

### SUMMARY OF THE INVENTION

An object of the invention is to provide a method capable of surely filling a filler in a through hole or the bottom of a non-through hole having a small diameter and a large aspect ratio.

In order to achieve the foregoing object, the invention is concerned with a method for filling a through hole or a non-through hole formed on a board with a fluent filler, which comprises combining at least one filling method selected from a centrifugal filling method and a magnetic filling method with an ultrasonic filling method.

The “centrifugal filling method” as referred to in the invention is a method in which a board having a through hole or a non-through hole is rotated, and a centrifugal force generated at that time is utilized for filling the through hole or non-through hole with the fluent filler. One specific example is spinning of the board at an appropriate rotation number.

The “magnetic filling method” as referred to herein is a method in which a magnetic force is given from the outside of the board to apply a magnetic action to a magnetic component contained in the fluent filler, and the magnetic action is utilized for filling the through hole or non-through hole with the fluent filler.

A characteristic feature of the invention resides in a point that the fluent filler with conductivity is filled in the through hole or non-through hole formed on the board by combining at least one filling methods elected from the foregoing filling methods with the ultrasonic filling method.

The “ultrasonic filling method” is a method in which the foregoing fluent filler is filled in the through hole or non-through hole while giving ultrasonic vibration to the fluent filler. As a method for giving ultrasonic vibration to the fluent filter, first of all, a method for injecting the fluent filler into the inside of the through hole or non-through hole while giving ultrasonic vibration to the board having the through hole or non-through hole formed thereon is considerable. The ultrasonic vibration given to the board is transmitted to the fluent filler during a process of injection into the inside of the through hole or non-through hole, whereby the fluent filler is excited by ultrasonic waves.

Another method for giving ultrasonic vibration to the fluent filler is a method in which during injecting the fluent filler into the inside of the through hole or non-through hole by stencil printing or the like, the ultrasonic vibration is given to printing means, for example, a squeeze. In the stencil printing process, the ultrasonic vibration given to the squeeze is transmitted to the fluent filler, whereby the fluent filler is excited by ultrasonic waves.

According to a combination of the foregoing two kinds of filling methods, for example, with respect to a hole having a diameter of not more than 25 μm and an aspect ratio of 5 or more, not only in the case where the hole is a through hole but in the case where the hole is a non-through hole, it is possible to fill the fluent filler without producing an unfilled portion in the bottom thereof. The foregoing two kinds of filling methods may be carried out in a simultaneous, parallel manner or may be carried out in sequence.

In the invention, the fluent filler can contain a liquid viscous material, a metal or alloy powder or a metal or alloy fused material or the like. The composition components of such a fluent filler and the like are properly chosen depending upon the filling method to be employed. For example, in case of using the magnetic filling method, the fluent filler contains at least one kind of magnetic particle selected among Fe, Co and Ni or an alloy thereof. The amount of such a magnetic particle or its alloy can be chosen within the range of from 30 to 100% by weight of the fluent filler.

In achieving the filling, a step of subjecting the fluent filler to stencil printing on one surface of the board on which the through hole or non-through hole is opened can be included. During or after this step of stencil printing, the foregoing filling methods are carried out. In case of applying the ultrasonic filling method, the ultrasonic vibration can be given to the squeeze or board. The thickness of the fluent filler to be printed by stencil printing is preferably a thickness corresponding to the depth of the through hole or non-through hole. According to this, substantially the majority of the fluent filler to be printed in the opening of the through hole or non-through hole on one surface of the board is filled in the inside of the through hole or non-through hole. In case of stencil printing, a liquid viscous material suitable for printing, specially a paste, and representatively a nanoparticulate paste is used as the fluent filler.

### BRIEF DESCRIPTION OF THE DRAWINGS

FIG. 1 is a microscopic photograph of a cross section of a sample obtained in Example 1 of the invention;

FIG. 2 is a microscopic photograph of a cross section of a sample obtained in Comparative Example 1; and

FIG. 3 is a microscopic photograph of a cross section of a sample obtained in Example 4 of the invention.

### DESCRIPTION OF THE PREFERRED EMBODIMENTS

### 1. Combined Use of Centrifugal Filling Method and Ultrasonic Filling Method

### EXAMPLE 1

1,000,000 non-through holes having a diameter of about 23 μm, a hole depth of about 167 μm and an aspect ratio of about 7 were formed on a board configured of a 200 mm-thick wafer. A nanoparticulate paste was subjected to stencil printing while giving ultrasonic vibration (55 to 66 kHz) to this board. As the nanoparticulate paste, one containing a nanoparticle of gold (Au) as a major component and containing nanoparticles of bismuth (Bi), antimony (Sb) and gallium (Ga) was used. This nanoparticulate paste has a low melting point and when solidified, exhibits volume expansion properties to be caused due to properties of bismuth (Bi) (solidification expandable low-melting nanoparticulate paste). The ultrasonic vibration was also given to both a stencil and a squeeze. The ultrasonic vibration, however, may be given only to the stencil.

Subsequently, the board was rotated at a high speed (rotation number: 2,000 rpm) for 5 minutes while giving ultrasonic vibration (55 to 66 kHz) to the board, thereby filling and impregnating the heat melted solidification expandable low-melting nanoparticulate paste in the inside of the non-through hole by utilizing a centrifugal force, followed by solidification. This is designated as Example 1.

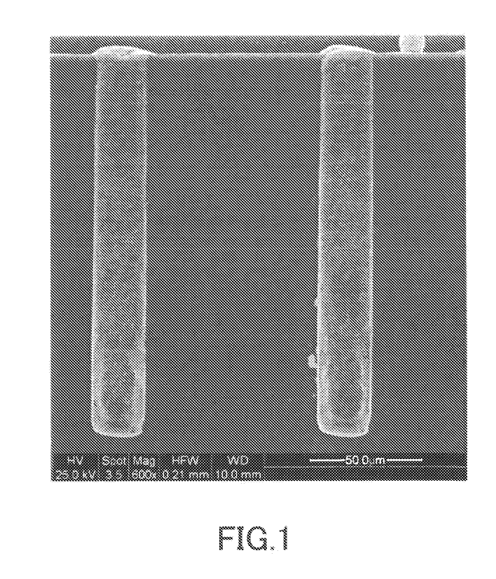

A microscopic photograph of a cross-sectional surface of a sample obtained in Example 1 is shown in FIG. 1. The nanoparticulate paste is completely filled and impregnated to an extent of the bottom of the non-through hole.

### COMPARATIVE EXAMPLE 1

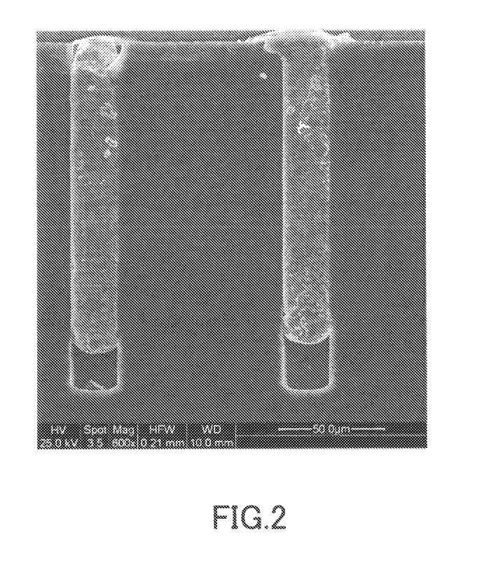

The same operations as in Example 1 were carried out without giving the ultrasonic vibration. This is designated as Comparative Example 1. A microscopic photograph of a cross-sectional surface of a sample obtained in Comparative Example 1 is shown in FIG. 2. The nanoparticulate paste was not completely filled to an extent of the bottom of the non-through hole, and a space remained in the bottom.

### EXAMPLE 2

An operation for carrying out stencil printing and centrifugal filling while giving ultrasonic vibration was repeated twice, and a board was heated to solidify a nanoparticulate paste. This is designated as Example 2.

As a result of microscopic observation of a cross-sectional surface of a sample obtained in Example 2, the nanoparticulate paste is completely filled to an extent of the bottom of the non-through hole similar to the case of FIG. 1.

### COMPARATIVE EXAMPLE 2

The same operations as in Example 2 were carried out without giving the ultrasonic vibration to the board. This is designated as Comparative Example 2. As a result of microscopic observation of a cross-sectional surface of a sample obtained in Comparative Example 2, a space remained in the bottom of the non-through hole similar to the case of FIG. 2.

### EXAMPLE 3

The same operations as in Example 1 were followed, except for using a low-melting solder alloy powder containing a tin metal as a major component (melting point: 230° C., average particle size: 5 μm), thereby filling the powder in the non-through holes of the board. After filling, the solder alloy was melted by heating at 250° C. and finally cooled for solidification. As a result of microscopic observation of a cross-sectional surface, the solder alloy was completely filled to an extent of the bottom of the non-through hole.

### COMPARATIVE EXAMPLE 3

The same operations as in Example 3 were carried out without giving the ultrasonic vibration to the board. This is designated as Comparative Example 3. As a result of microscopic observation of a cross-sectional surface of a sample obtained in Comparative Example 3, a space remained in the bottom of the non-through hole similar to the case of FIG. 2.

### 2. Combined Use of Magnetic Filling Method and Ultrasonic Filling Method

### EXAMPLE 4

The treatment was carried out under the same condition as in Example 1, except for replacing the centrifugal filling method with a magnetic filling method. A nanoparticle of nickel (Ni) was contained in an amount of 80% by weight relative to the whole amount in the nanoparticulate paste. The magnetic field direction was made substantially vertical to the board surface, and a magnetic field intensity seen on the board surface was defined as 1 (T). This is designated as Example 4.

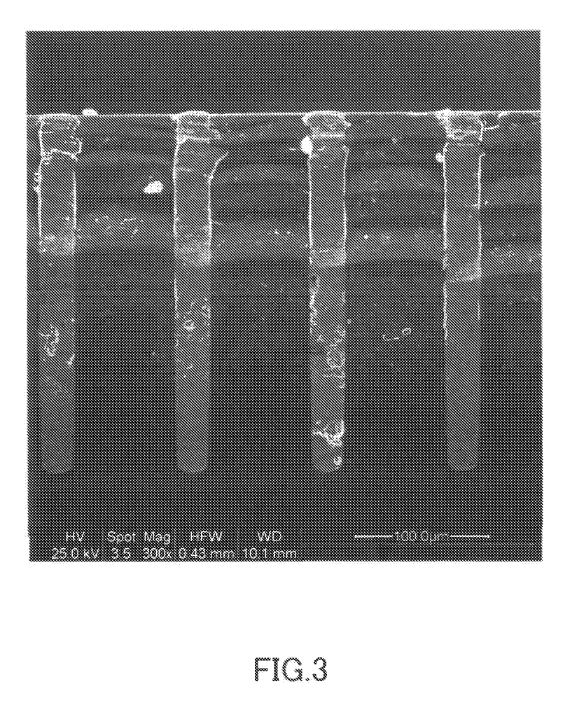

A microscopic photograph of a cross-sectional surface of a sample obtained in Example 4 is shown in FIG. 3. The nanoparticulate paste is completely filled and impregnated to an extent of the bottom of the non-through hole.

### COMPARATIVE EXAMPLE 4

The same operations as in Example 4 were carried out without giving the ultrasonic vibration to the board. This is designated as Comparative Example 4. As a result of microscopic observation of a cross-sectional surface of a sample obtained in Comparative Example 4, a space remained in the bottom of the non-through hole similar to the case of FIG. 2.

### EXAMPLE 5

An operation for carrying out stencil printing and magnetic filling while giving ultrasonic vibration to the board described in Example 1 was repeated twice, and the board was heated to solidify a nanoparticulate paste. This is designated as Example 5.

As a result of microscopic observation of a cross-sectional surface of a sample obtained in Example 5, it was confirmed that the nanoparticulate paste was completely filled to an extent of the bottom of the non-through hole similar to the cases of FIGS. 1 and 3.

### COMPARATIVE EXAMPLE 5

The same operations as in Example 5 were carried out without giving the ultrasonic vibration. This is designated as Comparative Example 5. As a result of microscopic observation of a cross-sectional surface of a sample obtained in Comparative Example 5, the nanoparticulate paste was not completely filled to an extent of the bottom of the non-through hole, and a space was found in the bottom.

### EXAMPLE 6

The same operations as in Example 4 were followed, except for using a low-melting solder alloy powder containing a tin metal as a major component (melting point: 230° C., average particle size: 5 μm), thereby filling the powder in the non-through holes of the board. After filling, the solder alloy was melted by heating at 250° C. and finally cooled for solidification. As a result of microscopic observation of a cross-sectional surface, the solder alloy was completely filled and impregnated to an extent of the bottom of the non-through hole.

### COMPARATIVE EXAMPLE 6

In the case where the same operations as in Example 6 were carried out without giving the ultrasonic vibration to the board, the solder alloy was not completely filled and impregnated to an extent of the bottom of the non-through hole.

What is claimed is:

1. A method for filling a through hole or a non-through hole formed on a board with a fluent filler, which comprises
combining at least one filling method selected from a centrifugal filling method and a magnetic filling method with an ultrasonic filling method.

2. The method according to claim 1, wherein the centrifugal filling method is a method in which a board having a through hole or a non-through hole is rotated, and a centrifugal force generated at that time is utilized for filling the through hole or non-through hole with the fluent filler.

3. The method according to claim 1, wherein the magnetic filling method is a method in which a magnetic force is given from the outside of the board to apply a magnetic action to a magnetic component contained in the fluent filler, and the magnetic action is utilized for filling the through hole or non-through hole with the fluent filler.

4. The method according to claim 1, wherein the ultrasonic filling method is a method in which the fluent filler is filled in the through hole or non-through hole while giving ultrasonic vibration to the fluent filler.

5. The method according to claim 1, wherein at least one filling method selected from the centrifugal filling method and the magnetic filling method and the ultrasonic filling method are carried out in a simultaneous, parallel manner.

6. The method according to claim 1, wherein at least one filling method selected from the centrifugal filling method and the magnetic filling method and the ultrasonic filling method are carried out in sequence.

7. The method according to claim 1, wherein the fluent filler is any one member selected among a liquid viscous material, a metal or alloy powder and a metal or alloy fused material.

8. The method according to claim 1, including a step of subjecting the fluent filler to stencil printing on one surface of the board on which the through hole or non-through hole is opened, wherein the ultrasonic filling method is carried out in this step.

9. The method according to claim 1, wherein the fluent filler contains a magnetic component, and the magnetic filling method is employed.
